(19) United States
(12) Patent Application Publication
(10) Pub. No.: US 2005/0103378 A1
(43) Pub. Date: May 19, 2005

(54) Hinged solar collector for a light

(76) Inventors: Mingqiang Pu, Xinhua Town (CN); Gustav P. Kuelbs, Dallas, TX (US)

Correspondence Address: Melvin A. Hunn;HILL & HUNN, LLP, Suite 1440, 201 Main Street, Fort Worth, TX, 76102-3105, US

(21) Appl. No.: 10/959,263

(22) Filed: Oct. 6, 2004

Related U.S. Application Data
(63) Continuation-in-part of application No. 10/830,657, filed on Apr. 23, 2004.
Application No. 10/830,657 is a continuation-in-part of application No. 29/178,330, filed on Mar. 24, 2003, now Pat. No. D494536.

(51) Int. Cl. H01L 31/00

(52) U.S. Cl. 136/291; 136/244

(57) ABSTRACT

A solar light is provided which includes a solar panel to convert solar energy to electrical energy to recharge a battery. A hinge allows a solar collector unit to pivot and rotate to allow positioning in a wide variety of angles. This enables the solar collector unit to be positioned perpendicular or more nearly perpendicular to sunlight rays while charging. A variety of hinges may be utilized, including a mono-axial hinge, a bi-axial hinge, a spherical hinge, or any other type of universal joint.

### BACKGROUND OF THE INVENTION

1. Field of the Invention

The present invention relates to solar lights. In particular, the present invention relates to solar collectors for solar lights.

2. Description of the Prior Art

Solar powered lights have been around for many years. The solar collector is typically installed on the top of the housing.

Because the housing is usually positioned so that the solar powered light illuminates in a particular direction, the solar collector is rarely positioned to maximize the solar energy from the sun.

For these reasons, many shortcomings remain in the area of solar powered lighting.

### SUMMARY OF THE INVENTION

There is a need for a hinged solar collector that can be adjusted to maximize the collection of solar energy, regardless of the position of the housing of the solar powered light.

Therefore, it is an objective of the present invention to provide a hinged solar collector that can be adjusted to maximize the collection of solar energy, regardless of the position of the housing of the solar powered light.

The above objective is achieved by providing a solar collector that is positioned on a post that extends up from the housing of the solar powered light. The post includes a hinge that allows the solar collector to rotate about two different axes. This allows the solar collector to be positioned so that it can maximize the collection of solar energy, regardless of the direction or orientation of the housing.

The above as well as additional objectives, features, and advantages will become apparent in the following description.

### BRIEF DESCRIPTION OF THE DRAWINGS

The novel features believed characteristic of the invention are set forth in the appended claims. The invention itself however, as well as a preferred mode of use, further objectives and advantages thereof, will best be understood by reference to the following detailed description of the preferred embodiment when read in conjunction with the accompanying drawings, wherein:

FIGS. 1 and 2 are perspective views of one embodiment of a hinged solar collector for a light according to the present invention.

FIG. 3 is a perspective view of the hinged solar collector for light according to one embodiment of the present invention.

FIG. 4 is a front view of the hinged solar collector for light according to one embodiment of the present invention of FIG. 3.

FIG. 5 is a right side view of the hinged solar collector for light according to one embodiment of the present invention of FIG. 3.

FIG. 6 is a left side view of the hinged solar collector for light according to one embodiment of the present invention of FIG. 3.

FIG. 7 is a rear view of the hinged solar collector for light according to t one embodiment of the present invention of FIG. 3.

FIG. 8 is a top view of the hinged solar collector for light according to one embodiment of the present invention of FIG. 3.

FIG. 9 is a bottom view of the hinged solar collector for light according to one embodiment of the present invention of FIG. 3.

FIG. 10 is a perspective view of a light without a hinged solar collector.

FIG. 11 is a perspective view of one embodiment of a light with a hinged solar collector according to another embodiment of the present invention.

FIG. 12 is a perspective view of a hinged solar collector according to another embodiment of the present invention.

FIG. 13 is a perspective view of a hinged solar collector of FIG. 12 electrically connected to four lights.

FIG. 14 is a perspective view of a hinged solar collector of FIG. 12 electrically connected to four lights with hinged solar collectors.

FIG. 15 is a perspective view of three lights with hinged solar collectors, connected together electrically.

FIG. 16a is a perspective view of a first embodiment of a mono-axial hinge joint connecting a solar collector to a light.

FIG. 16b is a perspective view of a second embodiment of a mono-axial hinge joint connecting a solar collector to a light.

FIG. 16c is a perspective view of a third embodiment of a spherical hinge joint connecting a solar collector to a light.

FIG. 16d is a perspective view of a fourth embodiment of a mono-axial hinge joint connecting a solar collector to a light.

FIG. 17a is a perspective view of a first embodiment of a bi-axial hinge joint connecting a solar collector to a light.

FIG. 17b is a perspective view of a second embodiment of a bi-axial hinge joint connecting a solar collector to a light.

FIG. 17c is a perspective view of a third embodiment of a bi-spherical hinge joint connecting a solar collector to a light.

FIG. 17d is a perspective view of a fourth embodiment of a bi-axial hinge joint connecting a solar collector to a light.

FIGS. 18a-c are perspective views of a light with a hinged solar collector connected by a spherical hinge joint, illustrating the solar collector adjusted to several different positions.

FIG. 19a-c are perspective views of a light with a hinged solar collector connected by a bi-spherical hinge joint, illustrating the solar collector adjusted to several different positions.

FIG. 20a-c are perspective views of a light with a hinged solar collector connected by a flexible shaft, illustrating the solar collector adjusted to several different positions.

FIGS. 21 through 24 depict a spotlight with a hinged solar collector.

### DETAILED DESCRIPTION OF THE INVENTION

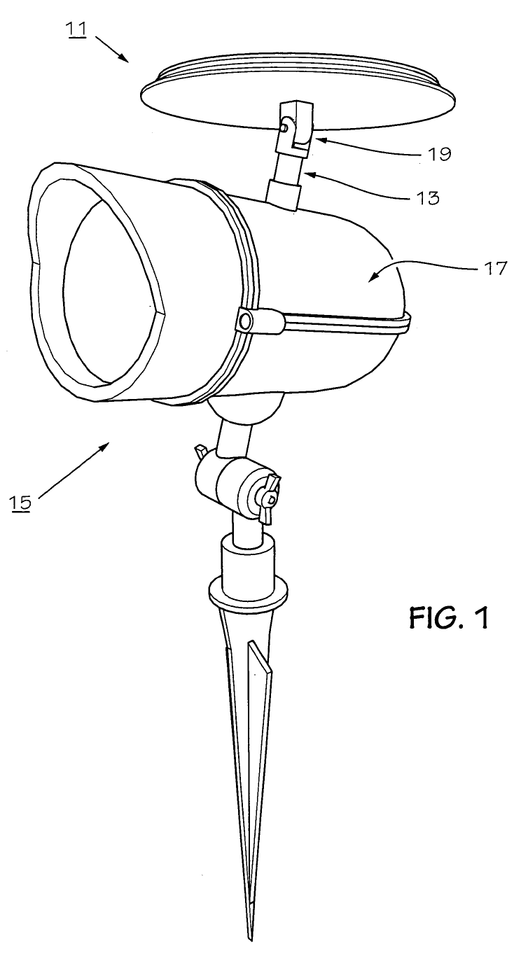

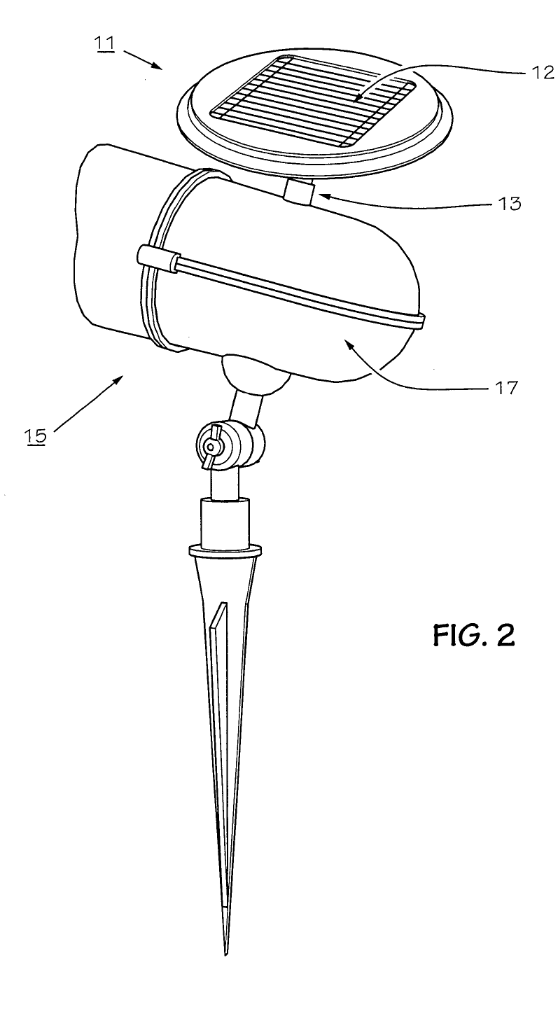

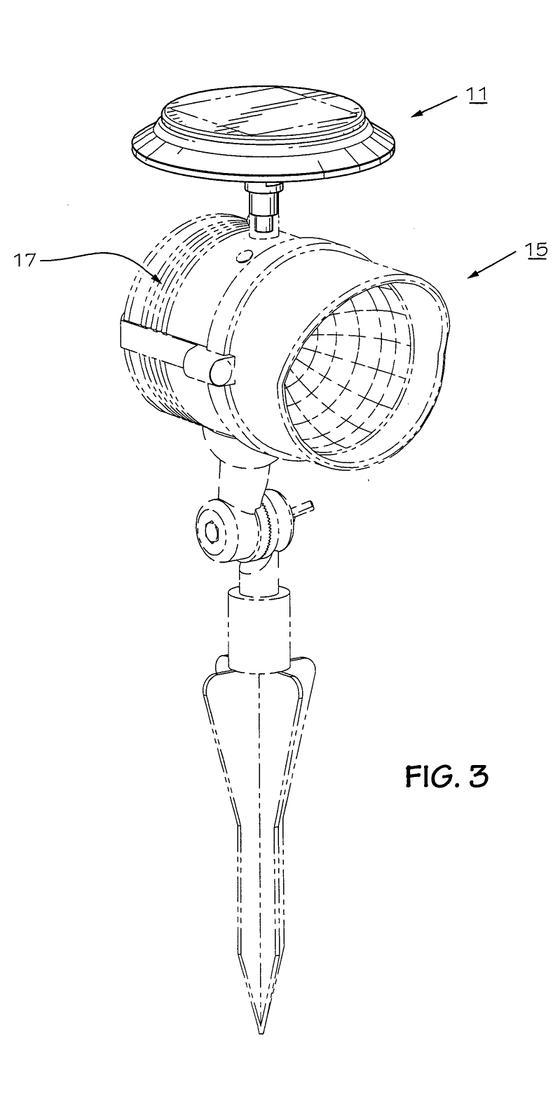

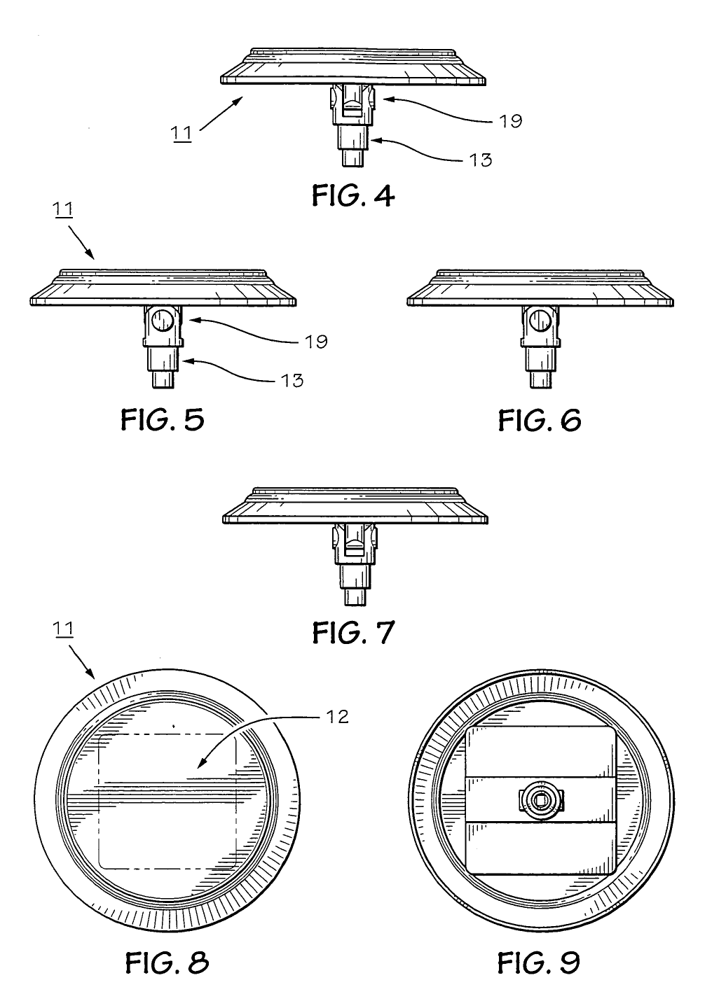

Referring to FIGS. 1 and 2 depict one embodiment of a hinged solar collector for a solar powered light is illustrated. As is shown a solar collector unit 11 is positioned at the top portion of a post 13. Solar collection unit 11 includes a conventional solar panel 12 and conventional wiring and circuitry (not shown) to allow the solar energy collected by solar panel to be converted into electrical energy and used to power or charge a solar powered light 15 or rechargeable battery (not shown). Post 13 is rotatably connected to a housing 17 of solar powered light 15 so that solar collector unit may rotate relative to housing 17. Post 13 includes a hinge means 19 that allows solar collector unit 11 to pivot about the lower portion of post 13 and rotate relative to housing 17. This configuration allows solar collector unit 11 to be positioned at a wide variety of angles relative to housing 17.

Because solar collector unit 11 can be positioned independent of housing 17, solar collector unit 11 can be oriented so as to maximize its collection of solar energy, and housing 15 can be oriented to illuminate a desired object or area. This enables solar panel 12 to be perpendicular or more nearly perpendicular to sunlight rays while solar powered light 15 is in charging mode, while enabling, without need of later adjustment, or with less adjustment required by a user, solar powered light 15 to be aimed and cast in lighting mode in a position conducive to applications used by outdoor spotlights, such as aimed at a statue, tree or mailbox, for a purpose of decorative or utilitarian effect.

Although hinge means 19 is shown as a mono-axial hinge, it should be understood that a bi-axial hinge, a spherical hinge, or any other type of universal joint could also be used. It will be appreciated additional hinge means and extensions may also be utilized to achieved the desired mobility of solar collector unit 11.

In the preferred embodiment, post 13 includes one or more internal stop means that limit the rotation of post 13. This prevents damage to any wiring that may be installed within post 13.

A lighting array utilizing light housings with attached solar collectors has several benefits.

First, by eliminating the need for a separate solar collector assembly, it simplifies installation by reducing labor and by eliminating extra wires that could become tangled and damaged.

Second, by eliminating the separate collector assembly, the number of visual components in the lighting array is reduced, and improving the aesthetics of the array.

Third, each collector can be uniquely positioned to maximize energy collection, given each collector's own position and light obstructions, allowing the array as a whole to collect the maximum possible amount of solar energy throughout the day. A single solar collector assembly will not track the sun's position throughout the day, so its collection efficiency will be reduced during certain periods of the day.

Fourth, by electrically connecting each individual light assembly to the array, each solar collector can contribute to the total energy collection and each light can share the stored energy, allowing each light to have the same illumination performance.

In some cases, the use of an additional, separate solar collection assembly can be beneficial.

First, when the lights are positioned for proper illumination of a scene, the lights may not be in ideal positions to collect solar energy, or their view of the sun may be blocked by obstructions. A separate solar collector assembly allows additional energy collection in this case.

Second, it may be possible to put a separate solar collector assembly out of view of the scene, improving the aesthetics of the lighting array and scene.

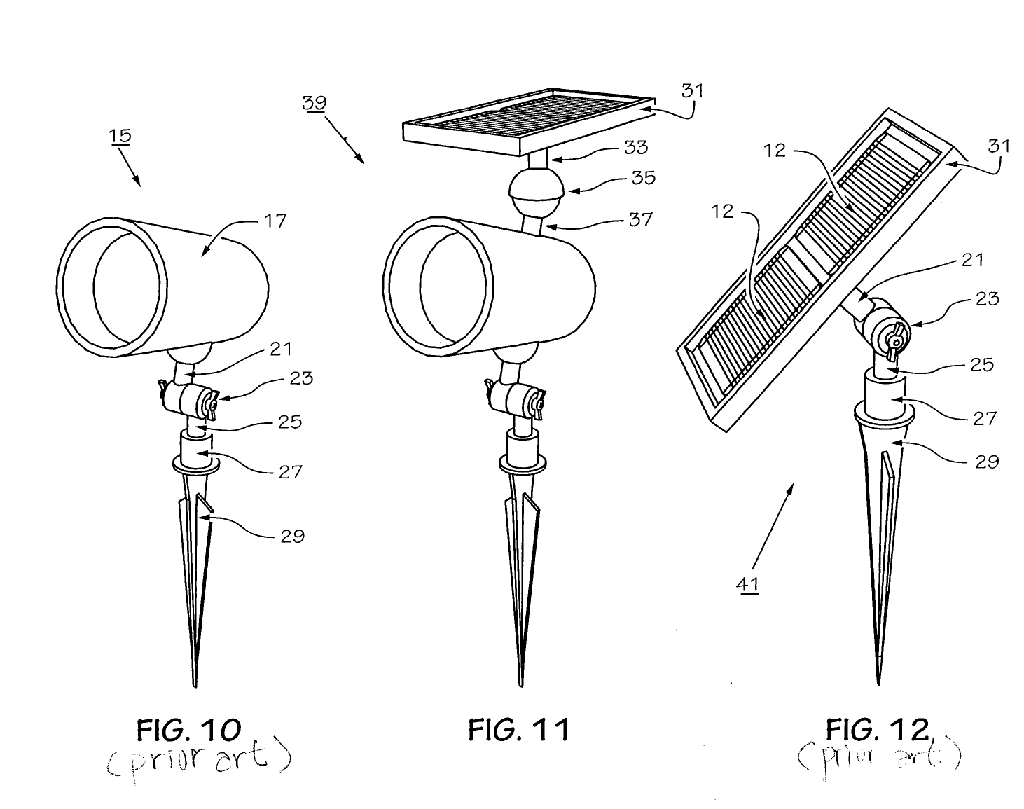

Referring to FIG. 10, a prior art example of a solar powered light 15 is shown. As is shown, a light housing 17 is positioned at the top portion 21 of a post. Post includes a hinge means 23 that allows light housing to pivot about the lower portion 25 of post. Lower portion of post is rotatably connected 27 to ground stake 29 which provides support for the light housing 17. This configuration allows light housing 17 to be positioned at a wide variety of angles relative to ground stake 29.

Referring to FIG. 11, an alternate embodiment of a hinged solar collector for a solar powered light is illustrated. As is shown a solar collector unit 31 is positioned at the top portion of a post 33. Solar collection unit 31 includes a conventional solar panel 12 and conventional wiring and circuitry (not shown) to allow the solar energy collected by solar panel to be converted into electrical energy and used to power or charge a solar powered light or rechargeable battery (not shown). Post 33 includes a spherical hinge means 35 that allows solar collector unit 31 to pivot and rotate about the lower portion of post 33 and rotate relative to light housing 17. This configuration allows solar collector unit 31 to be positioned at a wide variety of angles relative to housing 17.

Referring to FIG. 12, a prior art example of a solar collector assembly is shown. As is shown, a solar collector unit 31 is positioned at the top portion 21 of a post. Post includes a hinge means 23 that allows collector to pivot about the lower portion 25 of post. Lower portion 25 of post is rotatably connected 27 to ground stake 29 which provides support for the collector. The solar collector can be positioned independent of ground stake to maximize its collection of solar energy which is typically perpendicular to sunlight rays.

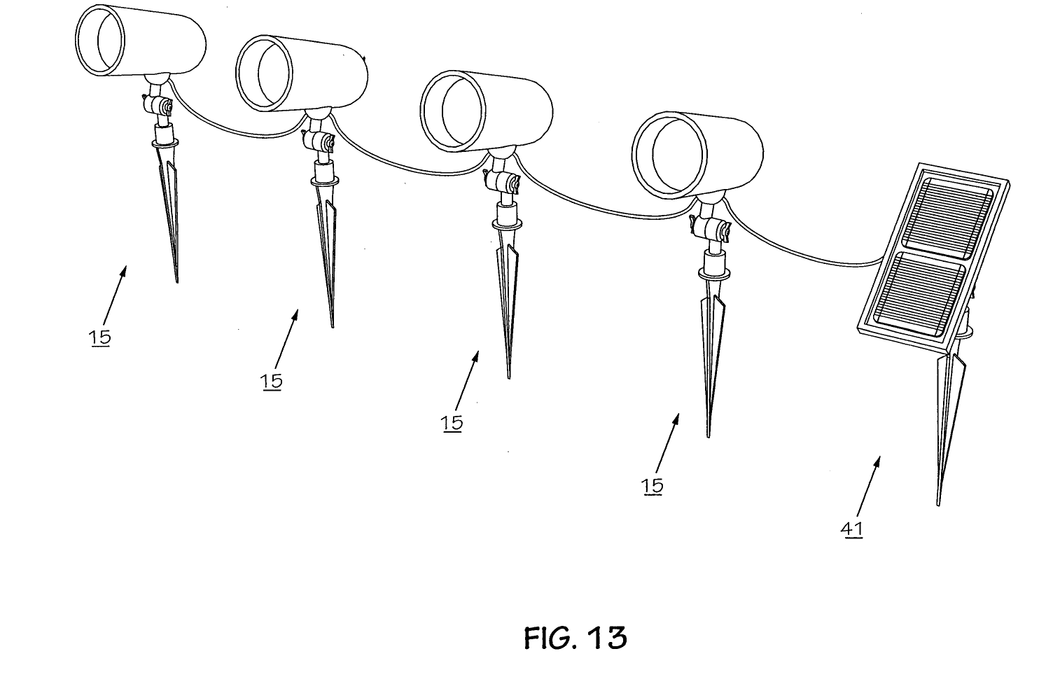

Referring to FIG. 13, a solar powered lighting array is shown. A solar collector assembly 41 is electrically attached to an array of solar powered lights 15. It should be understood that the lighting array may utilize one or more lights 15, and the array may utilize one or more solar collector assemblies 41. The lights can be individually located and oriented to illuminate a desired object, objects or area, while the solar collector assembly may be independently located and oriented to maximize the collection of solar energy.

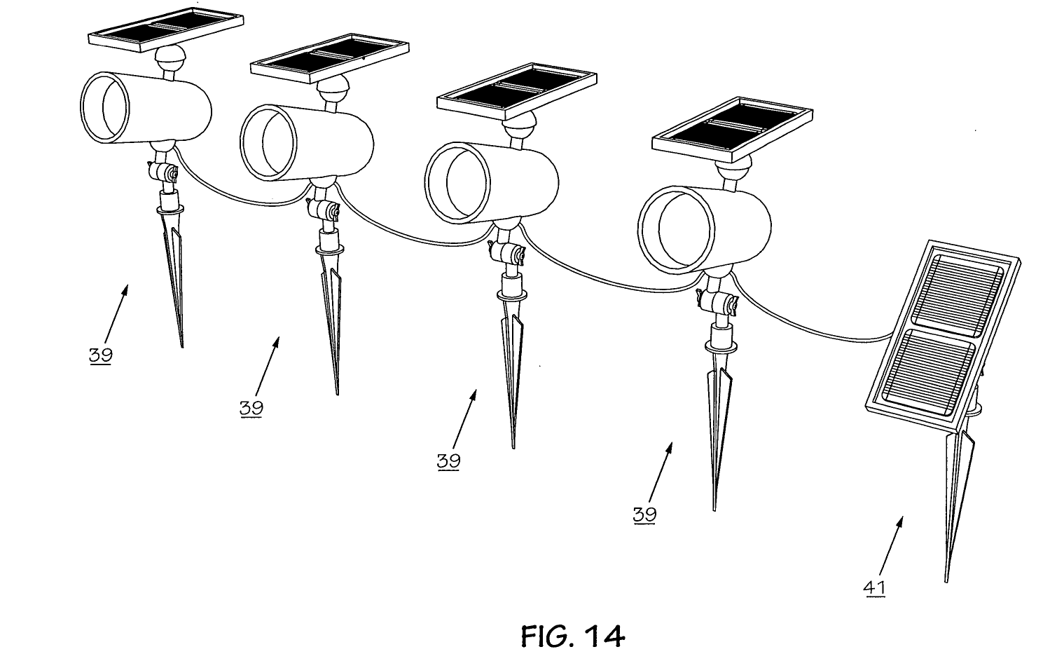

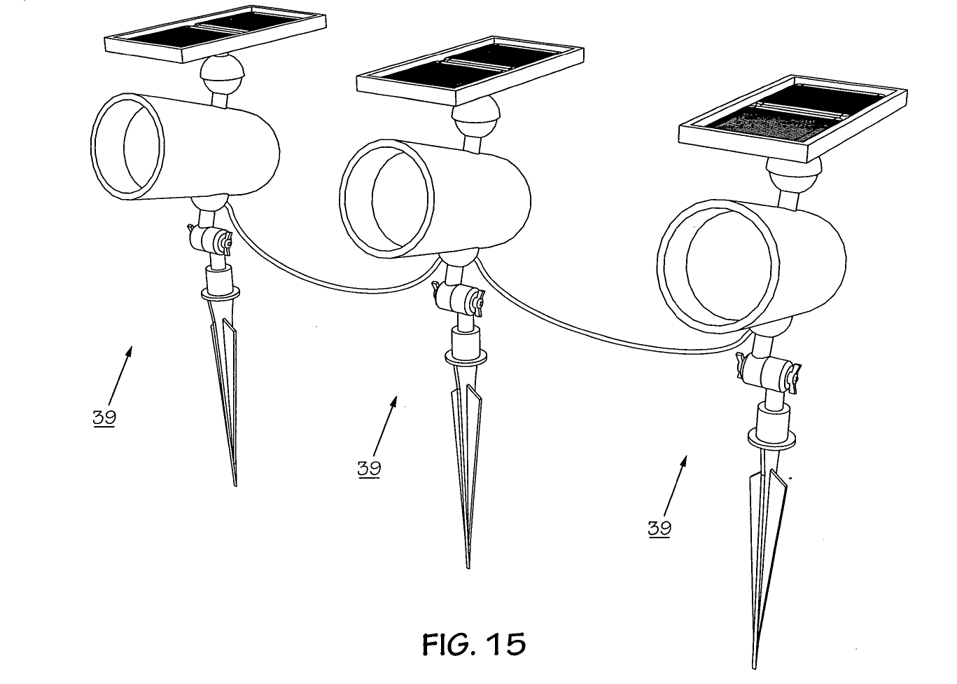

Referring to FIG. 14, a solar powered lighting array is shown. A solar collector assembly 41 is electrically attached to an array of solar powered light assemblies 39, each light assembly 39 being comprised of a solar powered light 15 with an attached solar collector unit 31. It should be understood that the lighting array can utilize one or more light assemblies 39, and can also utilize one or more solar collector assemblies 41. Further, the array can utilize both solar light assemblies 39 with attached solar collectors and lights 15 without attached collectors. Even though the individual solar light assemblies contain attached solar collectors, the addition of solar collectors assemblies 41 allows additional energy collection in the case that the lights may not receive sufficient solar energy in their unique locations and positions. Also, a separate collector assembly allows the collector assembly to be put out of view of the lights which are positioned relative to a scene interest which is in view.

Referring to FIG. 15, a solar powered lighting array is shown. In this embodiment, solar powered light assemblies 39 are electrically connected. It should be understood that the lighting array can utilize both solar light assemblies 39 with attached solar collectors and lights 15 without attached collectors. By utilizing solar light assemblies with attached solar collectors, the installation of the array is simplified by eliminating a separate solar collector assembly and the extra wiring that provides an additional opportunity for tangled and damaged wires.

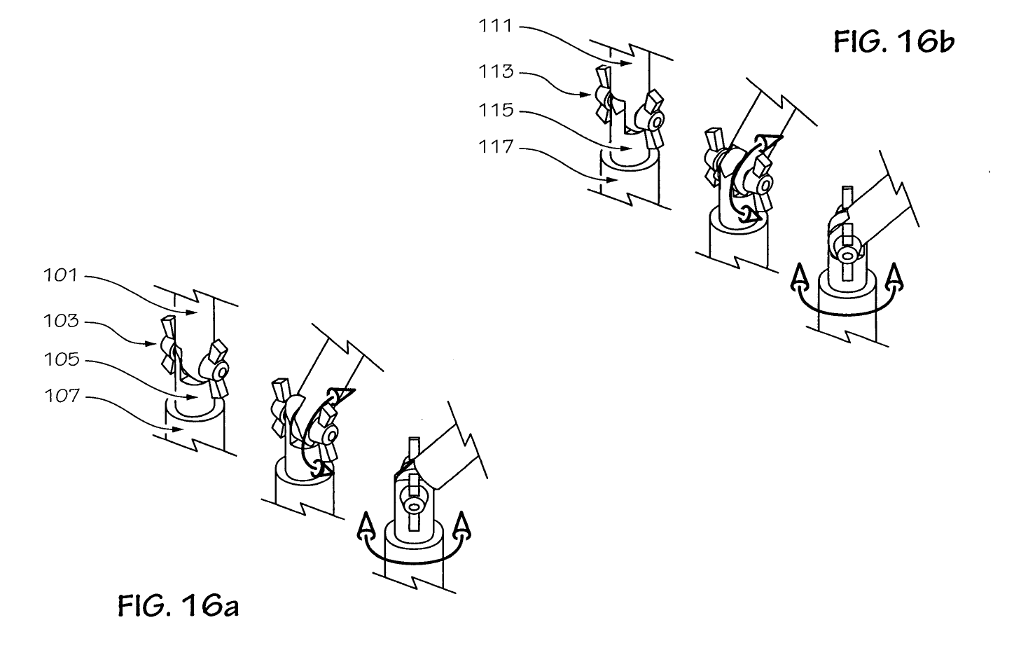

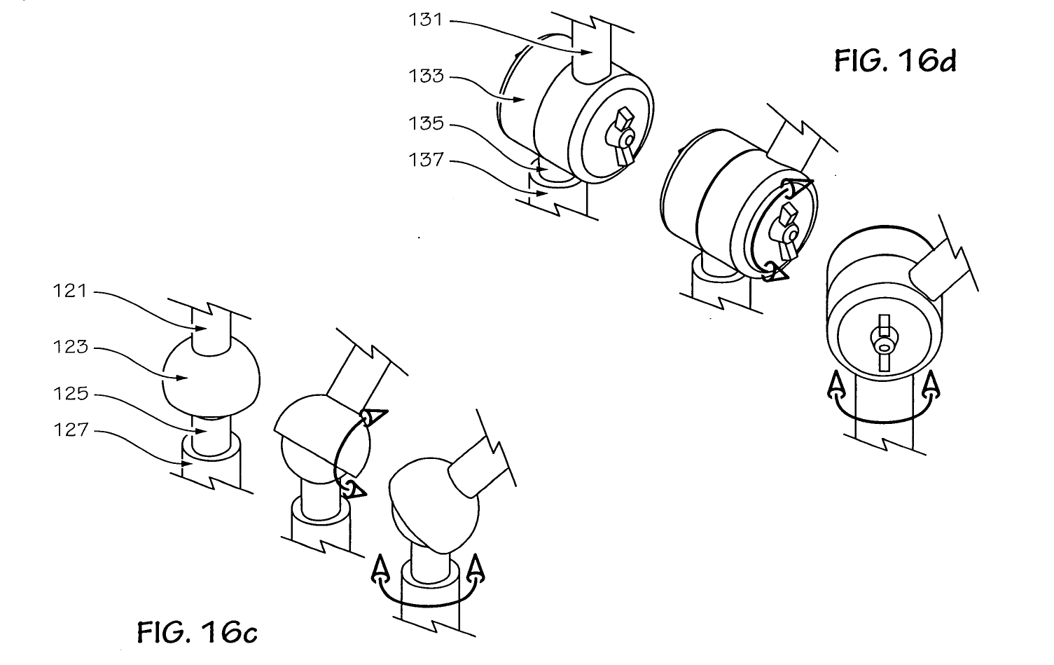

Referring to FIGS. 16a thru 16c, several embodiments of single-hinge joints are shown.

Referring to FIG. 16a, one embodiment of a mono-axial hinge joint is shown. Upper portion 101 of post is connected to solar collector and lower portion 105 is rotatably connected 107 to light housing. Upper portion 101 is connected to lower portion 105 with a hinge joint 103. Post may be limited by one or more internal stop means that limit the rotation of post relative to housing. This prevents damage to any wiring that may be installed within post. Hinge 103 may be limited by one or more internal stop means that limit the range of rotation of upper portion 101 relative to lower portion 105. In addition, hinge 103 may have internal means such as a crenellated surface that restricts rotation to discreet positions.

Referring to FIG. 16b, another embodiment of a mono-axial hinge joint is shown.

Upper portion 111 of post is connected to solar collector and lower portion 115 is rotatably connected 117 to light housing. Upper portion 111 is connected to lower portion 115 with a hinge joint 113. Post may be limited by one or more internal stop means that limit the rotation of post relative to housing. This prevents damage to any wiring that may be installed within post. Hinge 113 may be limited by one or more internal stop means that limit the range of rotation of upper portion 111 relative to lower portion 115. In addition, hinge 113 may have internal means such as a crenellated surface that restricts rotation to discreet positions.

Referring to FIG. 16c, an embodiment of a spherical joint is shown. Upper portion 121 of post is connected to solar collector, lower portion 125 is connected to light housing, and upper portion 121 is connected to lower portion 125 with a spherical joint 123. While the spherical joint 123 could allow rotation of upper portion 121 about its own axis, lower portion 125 may optionally be rotatably connected at connector 127 to light housing. Spherical joint may be limited by one or more internal stop means that limit the angular deviation of upper portion relative to lower portion. Also, spherical joint may be limited by one or more internal stop means that limit the rotation of upper portion about its axis, and rotatable connection 127 may be limited by one or more internal stop means that limit the rotation of lower portion about its axis. These limiting means prevent damage to any wiring that may be installed within post.

Referring to FIG. 16d, another embodiment of a mono-axial hinge joint is shown. Upper portion 131 of post is connected to solar collector and lower portion 135 is rotatably connected at connector 137 to light housing. Upper portion 131 is connected to lower portion 135 with a hinge joint 133. Post may be limited by one or more internal stop means that limit the rotation of post relative to housing. This prevents damage to any wiring that may be installed within post. Hinge 133 may be limited by one or more internal stop means that limit the range of rotation of upper portion 131 relative to lower portion 135. In addition, hinge 133 may have internal means such as a crenellated surface that restricts rotation to discreet positions.

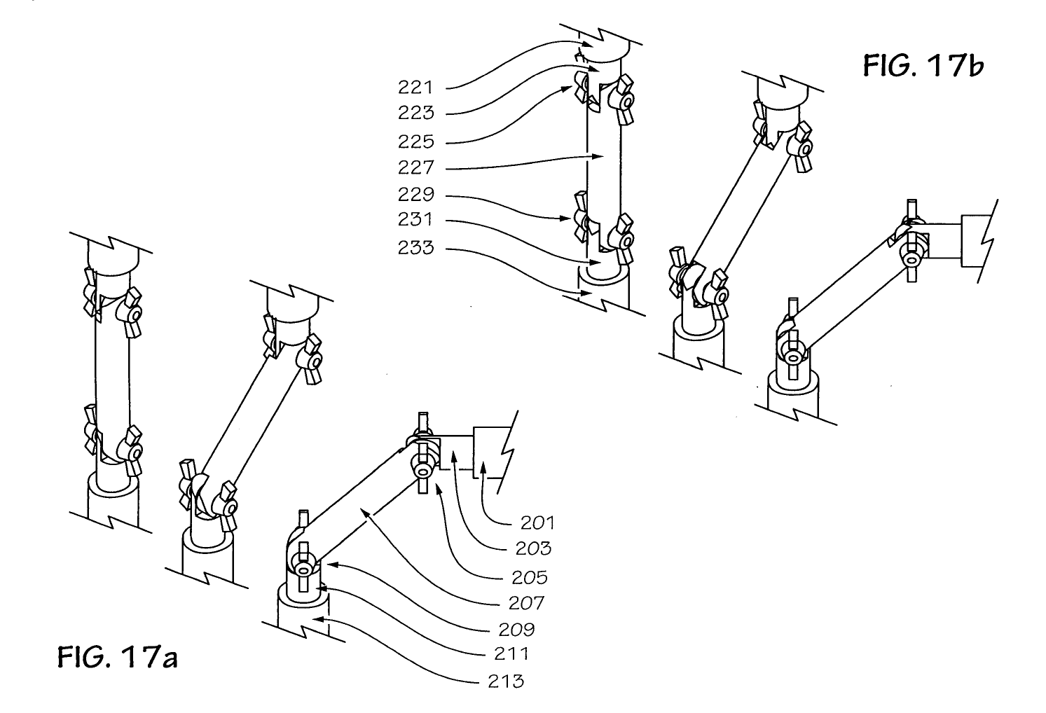

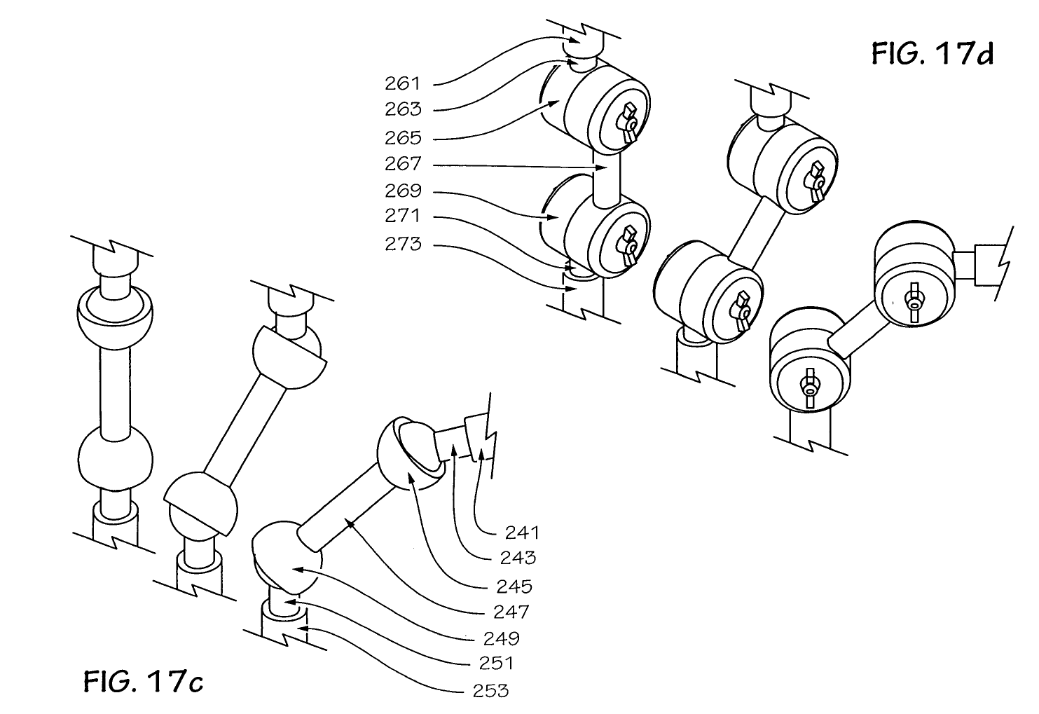

Referring to FIGS. 17a thru 17c, several embodiments of dual-hinge joints are shown.

A dual-hinge joint has benefits over a single hinge joint. First, a dual-hinge joint with a connecting portion may allow more freedom of movement of a solar collector relative to the light housing by eliminating interference between the collector and light housing that results from their overall dimensions. For example, when the connecting portion is short, the edge of the solar collector may interfere with the light housing with only a small amount of angular deviation of the collector. By lengthening the connecting portion, the solar collector may be able to deviate by 90 degrees or more before encountering interference with the light housing.

Second, in the case of a bi-axial hinge, the axes of each hinge need not be parallel. This allows the post and hinge design to be simplified by eliminating the need for a rotating coupling between the post and collector or post and light housing. For example, by making the axis of one hinge orthogonal to the axis of the second hinge, a full range of movement can be achieved, allowing the collector to be directed in any direction that the mono-axial hinge design with rotating coupling can achieve.

Referring to FIG. 17a, one embodiment of a bi-axial hinge joint is shown. Upper portion 203 of post may be rotatably connected 201 to solar collector, and lower portion 211 may be rotatably connected 213 to light housing. Upper portion is connected to middle portion 207 with a hinge joint 205, and middle portion is connected to lower portion with a hinge joint 209. Post may be limited by one or more internal stop means that limit the rotation of post relative to housing and the rotation of the solar collector relative to post. This prevents damage to any wiring that may be installed within post. Hinges may be limited by one or more internal stop means that limit the range of rotation of middle portion relative to upper portion and lower portion. In addition, hinges may have internal means such as a crenellated surface that restricts rotation to discreet positions.

Referring to FIG. 17b, another embodiment of a bi-axial hinge joint is shown.

Upper portion 223 of post may be rotatably connected 221 to solar collector, and lower portion 231 may be rotatably connected 233 to light housing. Upper portion is connected to middle portion 227 with a hinge joint 225, and middle portion is connected to lower portion 231 with a hinge joint 229. Post may be limited by one or more internal stop means that limit the rotation of post relative to housing and the rotation of the solar collector relative to post. This prevents damage to any wiring that may be installed within post. Hinges may be limited by one or more internal stop means that limit the range of rotation of middle portion relative to upper portion and lower portion. In addition, hinges may have internal means such as a crenellated surface that restricts rotation to discreet positions.

Referring to FIG. 17c, an embodiment of a dual-spherical joint is shown. Upper portion 243 of post is connected to solar collector, and lower portion 251 is connected to light housing. Upper portion is connected to middle portion 247 with a spherical joint 245, and middle portion is connected to lower portion with a spherical joint 249. While the spherical joints could allow rotation of portions about their own axes, upper portion may optionally be rotatably connected 241 to solar collector, and lower portion may optionally be rotatably connected 253 to light housing. Spherical joints may be limited by one or more internal stop means that limit the angular deviation of upper portion relative to middle portion, and angular deviation of middle portion relative to lower portion. Also, spherical joints and rotatable connections may be limited by one or more internal stop means that limit the rotation of post portion about their axes. These limiting means prevent damage to any wiring that may be installed within post.

Referring to FIG. 17d, another embodiment of a bi-axial hinge joint is shown. Upper portion 263 of post may be rotatably connected 261 to solar collector and lower portion 271 may be rotatably connected 273 to light housing. Upper portion is connected to middle portion 267 with a hinge joint 265, and middle portion is connected to lower portion 271 with a hinge joint 269. Post may be limited by one or more internal stop means that limit the rotation of post relative to housing and the rotation of the solar collector relative to post. This prevents damage to any wiring that may be installed within post. Hinges may be limited by one or more internal stop means that limit the range of rotation of middle portion relative to upper portion and lower portion. In addition, hinges may have internal means such as a crenellated surface that restricts rotation to discreet positions.

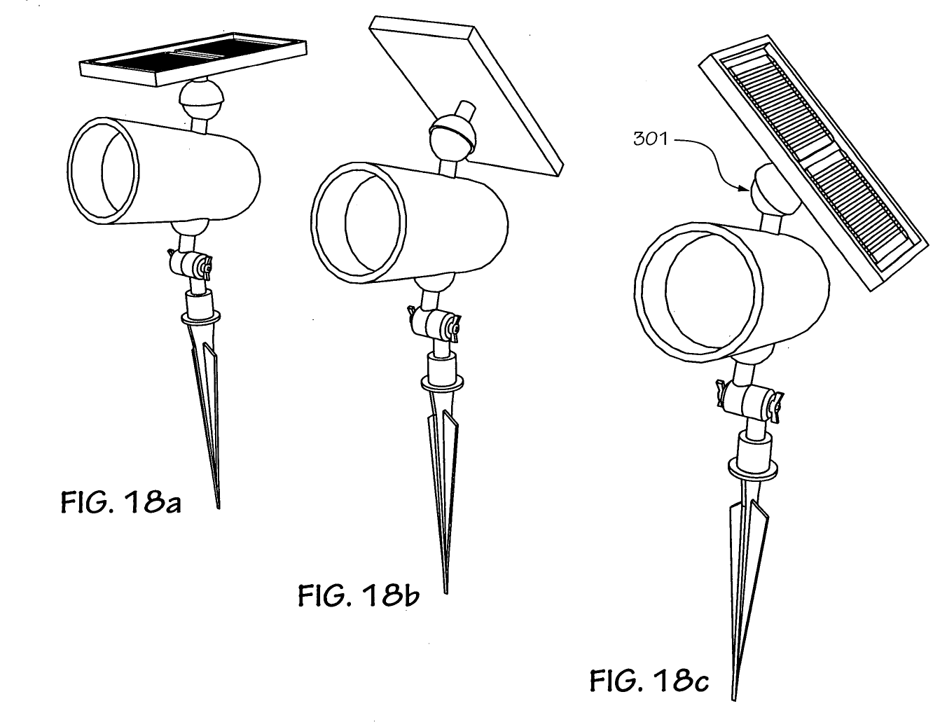

Referring to FIGS. 18a, 18b and 18c, an example of a light housing with attached solar collector is shown. The solar collector is connected to the light housing with a single spherical joint and is shown in several positions which illustrates the range of movement possible with this attachment mechanism.

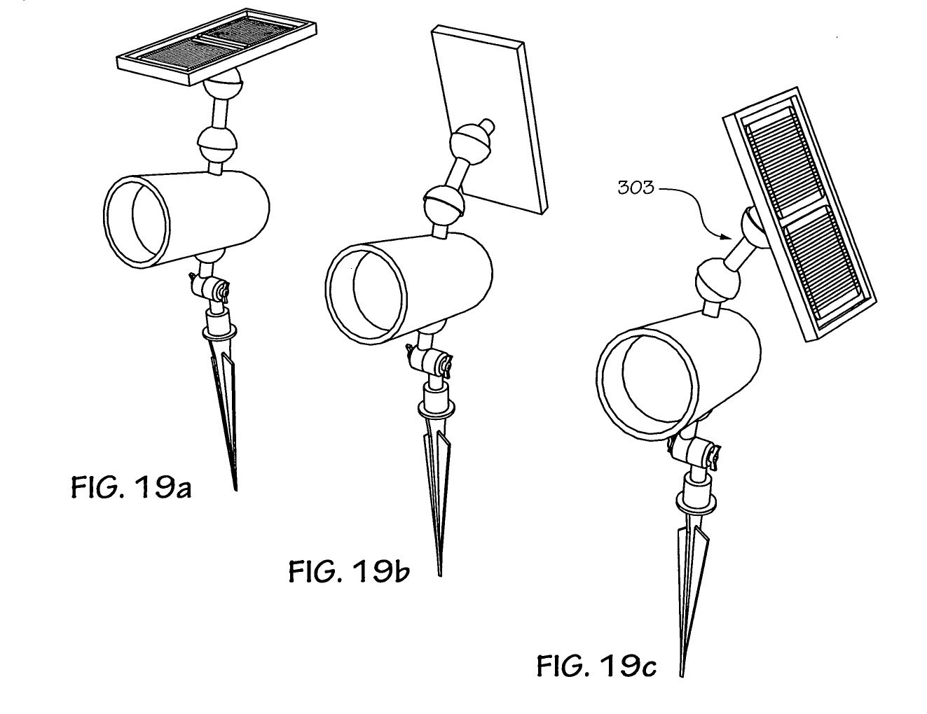

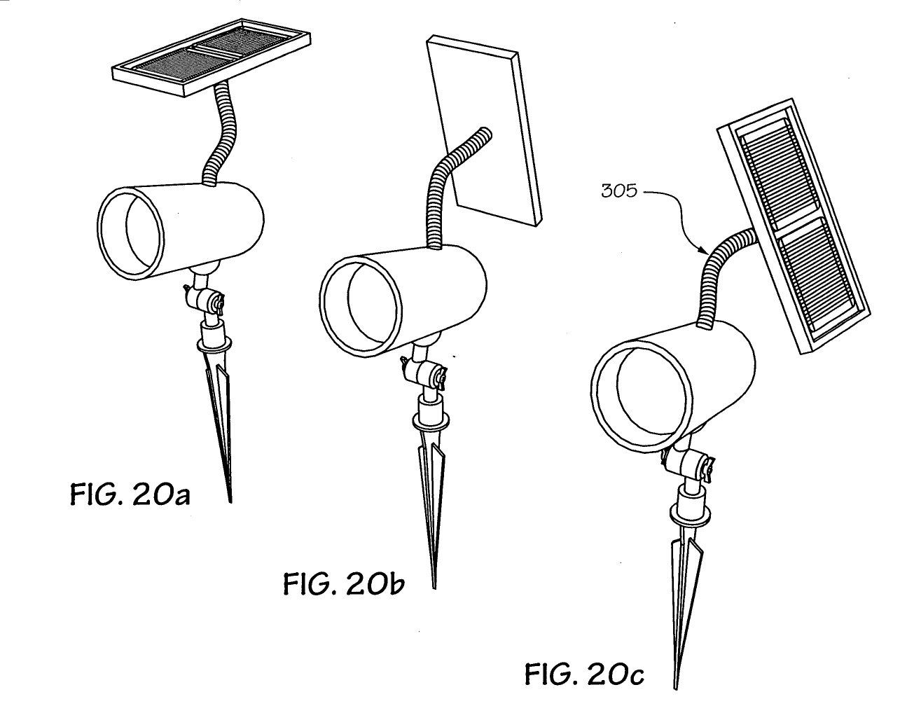

Referring to FIGS. 19a, 19b and 19c, another example of a light housing with attached solar collector is shown. The solar collector is connected to the light housing with a dual spherical joints and is shown in several positions which illustrates the range of movement possible with this attachment mechanism.

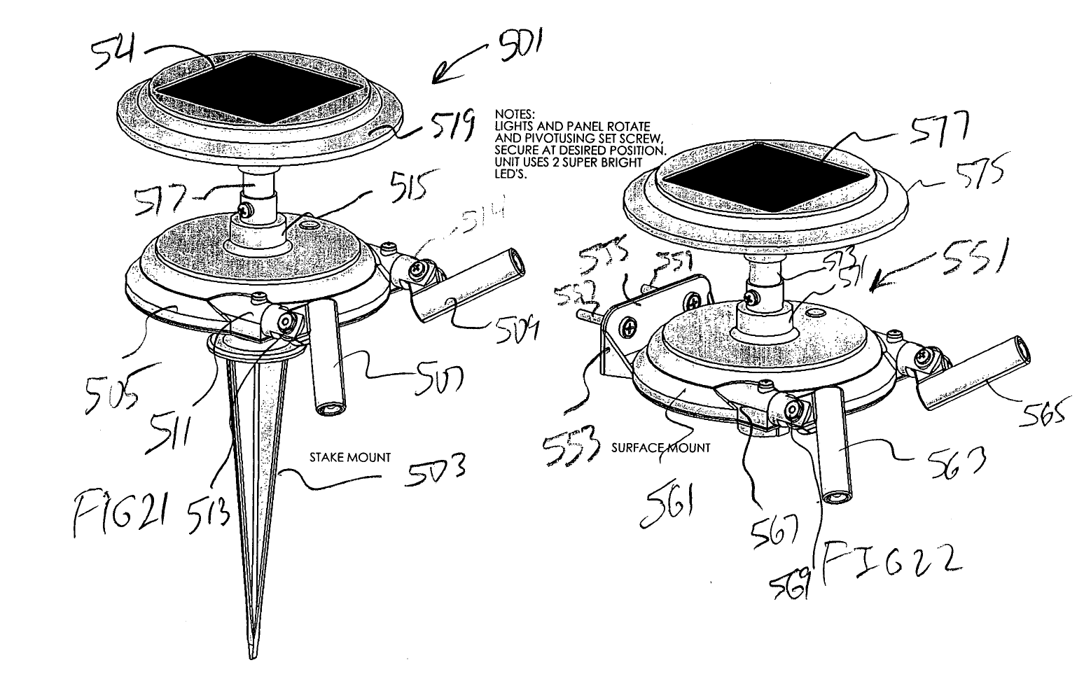

Referring to FIGS. 20a, 20b and 20c, another example of a light housing with attached solar collector is shown. The solar collector is connected to the light housing with a flexible shaft and is shown in several positions, which illustrates the range of movement possible with this attachment mechanism. A flexible shaft allows for greater flexibility in positioning, and may simplify manufacturing.

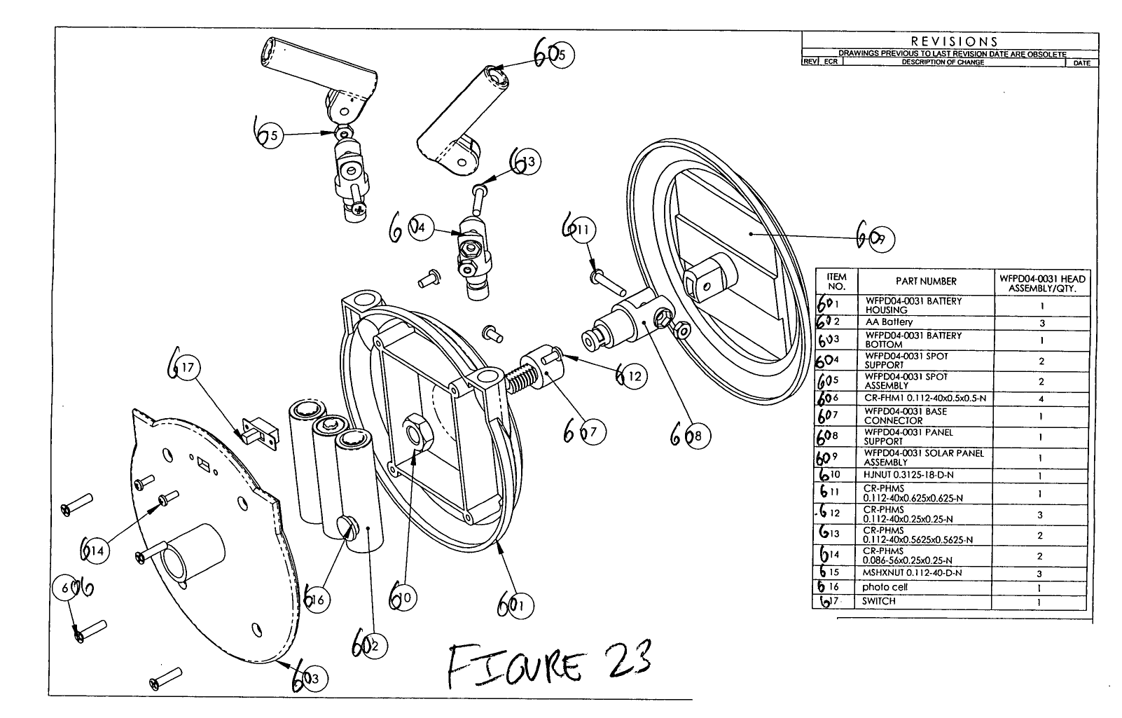

FIGS. 21 through 24 depict yet another embodiment of the present invention. Specifically, this embodiment provides for outdoor or lawn lighting which utilizes very bright LEDs to provide “spot” lighting. One or more LED spotlights may be coupled to the housing. Each LED spotlight is independently movable relative to the light housing and thus allows for all types of orientation of the spotlight.

FIG. 21 depicts outdoor light 501 which includes a stake portion 503, a housing portion 505 which, in this embodiment, is disc-shaped. Furthermore, outdoor light 501 includes LED spotlights 507, 509. Spotlight 507 may be oriented utilizing hinged joint 513. LED spotlight 509 may be oriented utilizing hinge joint 514. Any of the hinged joints discussed in the present application can be utilized to permit limited or maximum orientation of the LED lights 507, 509. LED light 507 is secured to housing 505 by mounting bracket 511. LED 509 is likewise secured to housing 505. A post 517 extends upward from housing 505 to connect solar connector 519 with solar panel 521. Mounting system 515 on housing 505 secures post 517 to housing 505. The solar collector 519 may be movable relative to housing 505 utilizing any of the hinged couplings discussed in the present application.

FIG. 22 depicts an alternative embodiment of the invention of FIG. 21. In this embodiment, no mounting stake is provided. Instead, a mounting bracket 553 is coupled to housing 516. It includes a mounting plate 555 which receives screws 557, 559 in order to secure outdoor light 551 to a surface such as the side of a building or a fence. In the embodiment depicted in FIG. 22, LED spotlights 563, 565 are secured to housing 561. Mounting systems 567 are utilized to secure the LED spotlights in a particular position relative to housing 561. An adjustable connection 569 may be utilized for each LED spotlight in order to allow particular orientations of the LED spotlights. Any of the hinged couplings discussed in the application can be utilized in order to permit orientation of the LED spotlights. The housing 561 is connected to solar connector 575 by post 513 which is secured to mounting system 571. A collector element 577 is carried by solar collector 575. Solar collector 575 may be coupled through a hinged coupling in order to permit the adjustment of solar collector 575 in order to maximize the recharging which can be obtained by solar collector 575. Any of the hinge connections discussed in this application can be utilized to connect solar collector 575 to post 573.

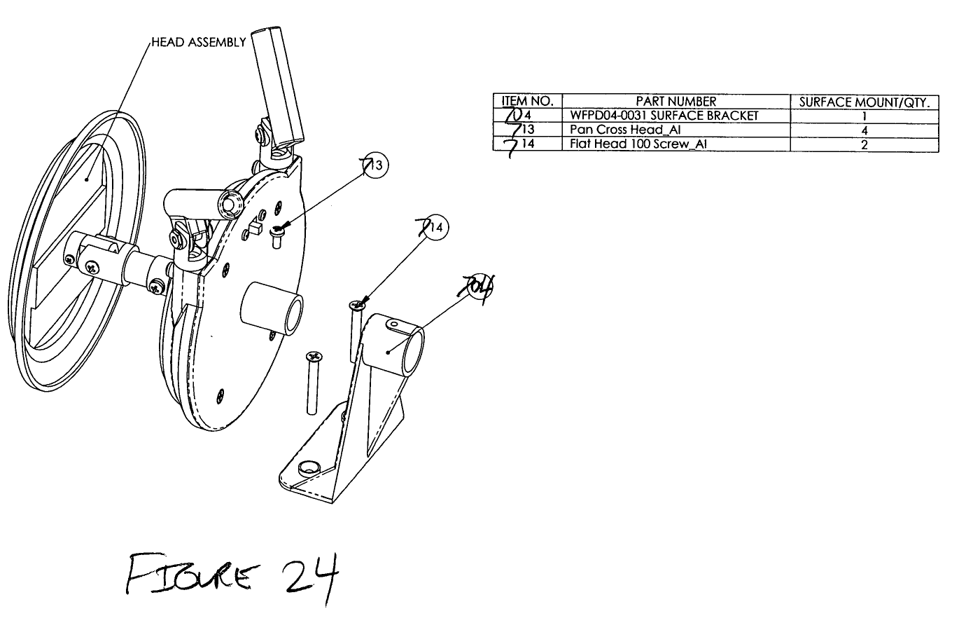

FIG. 23 depicts the embodiment of FIG. 21 in exploded form and illustrate the parts which are utilized to make-up the hinged solar collector with LED spotlights. As is shown, housing 601 receives and carries batteries 602. Battery plate 603 is provided to secure to battery housing 601 in order to maintain the batteries in a fixed position. Screws 606, 614 are utilized to secure plate 603 to housing 601. A nut 610 is carried within housing 601. It is adapted to couple to bolt 607. Pins 612 are utilized to secure the bolt to panel support 608. Panel support 608 includes a hinged coupling which is secured by screw 611. This permits solar panel assembly 609 to be moved relative to housing 601. As is also shown in the view of FIG. 23, spot assemblies 605 are provided to carry bright LED bulbs. Spot supports 604 are provided and include a hinged connector which allow for the movement of LED spots 605 relative to base 601.

FIG. 24 depicts in exploded form the embodiment of FIG. 22. As is shown, a surface bracket 704 is provided and secured to a flat surface utilizing flat head screws 713. Screw 713 is provided to secure bracket support 704 to a cylindrical extension on the bottom of the light housing.

Although the invention has been described with reference to a particular embodiment, this description is not meant to be construed in a limiting sense. Various modifications of the disclosed embodiments as well as alternative embodiments of the invention will become apparent to persons skilled in the art upon reference to the description of the invention. It is therefore contemplated that the appended claims will cover any such modifications or embodiments that fall within the scope of the invention.

1. A solar lawn light, comprising:
(a) a stake portion;
(b) a light housing portion;
(c) a solar collector;
(d) a swivel connection between said solar collector and said light housing portion; and
(e) wherein said swivel connection allows said solar collector to pivot relative to said light housing portion.

2. A solar lawn light, comprising:
(a) a stake portion;
(b) a light housing portion;
(c) a solar collector;
(d) a swivel connection between said solar collector and said light housing portion; and
(e) wherein said swivel connection comprises a spherical hinge

3. A solar lawn light, comprising:
(a) a stake portion;
(b) a light housing portion;
(c) a solar collector;
(d) a swivel connection between said solar collector and said light housing portion; and
(e) wherein said swivel connection comprises a mono-axial hinge joint.

4. A solar lawn light, comprising:
(a) a stake portion;
(b) a light housing portion;
(c) a solar collector;
(d) a swivel connection between said solar collector and said light housing portion; and
(e) wherein said swivel connection comprises a bi-axial hinge.

5. A solar lawn light, comprising:
(a) a stake portion;
(b) a light housing portion;
(c) a solar collector;
(d) a swivel connection between said solar collector and said light housing portion; and
(e) wherein said swivel connection comprises a dual-spherical joint.

6. A solar lawn light, comprising:
(a) a stake portion;
(b) a light housing portion;
(c) a solar collector;
(d) a swivel connection between said solar collector and said light housing portion; and
(e) wherein said swivel connection comprises a flexible shaft.

7. A solar lawn light, comprising:
(a) a stake portion;
(b) a light housing portion;
(c) a solar collector;
(d) a swivel connection between said solar collector and said light housing portion;
(e) at least one LED spotlight coupled to said light housing portion; and
(f) a swivel connection between said at least one LED spotlight and said light housing portion.
